(19) United States
(12) Patent Application Publication
(10) Pub. No.: US 2011/0025311 A1
(43) Pub. Date: Feb. 3, 2011

(54) MAGNETIC ROTARY SYSTEM FOR INPUT DEVICES

(75) Inventors: Nicolas Chauvin, Chexbres (CH); Olivier Theytaz, Savigny (CH)

Correspondence Address: THE LAW OFFICE OF DEEPTI PANCHAWAGH - JAIN, C/O CPA GLOBAL, PO BOX 52050, MINNEAPOLIS, MN, 55402, US

(73) Assignee: Logitech Europe S.A., Romanel-sur-Morges (CH)

(21) Appl. No.: 12/511,595

(22) Filed: Jul. 29, 2009

(51) Int. Cl. G01B 7/30; H05K 13/04

(52) U.S. Cl. 324/207.25; 29/729

(57) ABSTRACT

Embodiments of the present invention include a roller for an input device, where the roller's absolute angular position is measured by a magnetic encoder. A magnet is attached to the roller, possibly inside the roller so as to make the embodiment more compact. In one embodiment, the magnetization is simple and low cost. Further, tight tolerances are not required, and such a system is easy to manufacture. In one embodiment, the sensor is covered by any non-ferromagnetic material, to protect it from foreign particles, and to reduce ESD. In one embodiment, the wheel consumes much less power than conventional wheels in input devices. In one embodiment, the tilting of the wheel is measured using the same sensor that is used for measuring the rotation of the wheel. In one embodiment, a ratcheting feel provided to the user when rotating the wheel is synchronized with the rotation signal.

### BACKGROUND OF THE INVENTION

1. Field of the Invention

The present invention relates generally to an improved roller using magnetic encoders, and more particularly, to rollers using magnetic encoders in an input device, such as a mouse.

2. Description of the Related Arts

Input devices, such as a mouse or a trackball, are well-known peripherals for personal computers and workstations. Such input devices (or pointing devices) allow rapid relocation of the cursor on a display screen, and are useful in many text, database and graphical programs. Perhaps the most common form of pointing devices is the electronic mouse.

Most mice include several buttons (e.g., left click button, right click button, etc.), as well as a wheel/roller. Such a wheel is turned by a user's finger, and the rotation of such a wheel is measured and translated into various inputs such as scrolling through a document on the display associated with a host to which the mouse is coupled, zooming in/out in applications on the host, increasing/decreasing volume, and so on.

The rotation of the wheel can be measured in several ways. Some such ways, based upon differential sensing, are described in U.S. Pat. No. 5,680,157, entitled “Pointing Device with Differential Opto-Mechanical Sensing”, which is also owned by the assignee of the present invention, and which is incorporated herein by reference in its entirety. The pointing device described in the '157 patent includes one or more shaft encoders positioned to be rotated by movement of a rotational member.

Conventional rotational encoders are transmissive, and most common implementations today measure the movement of the wheel by using an optical encoder with a wheel having spokes and/or transparent areas alternating with non-transparent areas. Such a wheel is shown in FIG. 1A. A light source is typically located on one side of this wheel, and a sensor is located on the other side of the wheel. FIG. 1B provides a cross-sectional view of such a configuration.

There are several problems with the type of arrangement described in FIGS. 1A-1B. First, since the light source is on one side of the wheel, and the sensor is on the other side, each of these elements (light source and sensor) needs its own package. This leads to the requirement of a certain volume/space on both sides of the wheel, making the entire arrangement relatively large.

Second, since the light has to travel through the wheel to get to the sensor, part of the light is lost when it hits the non-transparent portions of the wheel (for example, the spokes of the wheel). This can be seen clearly in FIG. 1C. Such light may be absorbed by the non-transparent portion of the wheel, may be reflected or refracted by it, some combination of these, and so on. Since part of the light emitted by the light source is not received by the sensor, power is wasted. Further, the wheel is relatively wide and this puts some distance between the light source and the sensor. When the light source is an LED, the LED beam is divergent, and this results in a light intensity that decreases when the distance increases. All such loss of light intensity, and other power consumption issues, are extremely relevant, especially for wireless devices which depend upon a battery for power, and where battery life is an important consideration.

Other problems exist in conventional wheels in input devices. Many such devices allow tilting of the wheel for additional functionality (e.g. horizontal scrolling, etc.) In conventional systems, the light source and sensor are attached to a printed circuit board (PCB) in the device. When the wheel is tilted, the relative position of the wheel with respect to the beam changes, and thus the encoding of the motion of the wheel in the tilted position may be inaccurate. Spurious counts of the wheel are often generated, and are very annoying for the users. Additionally, separate sensors and/or switches are required to measure the tilt of the wheel. These additional components increase the cost, as well as require a large form factor.

Yet other problems exist with conventional wheels in input devices. Accurate mechanical alignment is required for such implementations, since light emitted by the light source needs to reach the optical sensor. Requirements of such tight tolerances make the manufacture of pointing devices more difficult and expensive.

Still other issues relate to synchronizing the ratcheting feel received by the user when rotating the wheel, with the signal sent by the wheel to the host device. If this ratcheting feel is not synchronized accurately, the user is confused by receiving a ratcheting feel separately from an action (e.g., scrolling to the next line) happening.

Still another problem encountered in these prior art implementations is that only the relative position of the rotation of the wheel (the incremental rotational changes) are measured. No indication is provided of the absolute angular position of the wheel. There are several issues with such incremental/relative measurement. Such issues include that counts are lost, leading to loss of data, loss of correlation between counts and wheel position, and loss of ratchet synchronization.

Some solutions partially address some of the issues described above, but not all. For instance, reflective encoders, such as those shown in FIGS. 2A and 2B, have both the light source and the sensor on the same side of the wheel. However, some of the other problems described above remain, and some new ones are introduced. For instance, as can be seen from FIGS. 2A-2B, reflective encoders also use an alternation of white (or highly reflective) and black (or highly absorbent) surfaces. Therefore with such conventional reflective encoders, half of the light energy is still lost, thus leading to power consumption issues, as with conventional transmissive encoders discussed above. Further, several of the other issues outlined above are not resolved.

Several ways of magnetic measurement of rotations have been implemented in other industries. For instance, some such solutions have been implemented in the automotive industry. However, for various reasons, these ways have not been implemented in pointing devices. Some of these have been discussed below.

FIGS. 3A-3D show multi-pole magnets which are used with incremental magnetic encoders. This type of measurement of angular position has been used in some places, such as in the automotive industry. However, this type of setup has not been used in pointing devices for several reasons. One reason is that such assemblies are expensive—it is expensive to magnetize multi-pole magnets. Another reason is that it is very difficult to accommodate so many magnetic poles in a small magnet, thus leading to a form factor that is too large to be desirable for implementations in devices with small for factors.

FIGS. 4A-4B and 5A-5B show diametral magnets with a single north and a single south pole, that are used with encoders that provide information on the absolute position of the magnet. These have been used in some automotive applications, as well as in other applications that require information regarding the absolute position (e.g., in compasses). FIGS. 4A and 4B show an implementation based on the dual-axis Hall sensor, while FIGS. 5A and 5B show an implementation based on vertical field measurements. However, such implementations are also not suitable for use in rollers in pointing devices for several reasons. One reason is that such implementations require large power consumption, which is not acceptable in pointing devices, especially in wireless ones which are becoming increasingly common. Another reason is that such configurations cannot measure the absolute position with a resolution as great as that required in pointing device implementations. In such systems, a resolution of better than one degree typically cannot be achieved. A much finer resolution is desired in pointing device implementations.

FIGS. 6A-6D show implementations with magneto-resistive encoders, using reluctance variation. Here the rotating wheel has teeth made of ferromagnetic material. In some implementations, a disk such as the one shown in FIG. 6C is used. In other implementations, a cup such as the one shown in FIG. 6D is used. However, these implementations are again not suitable for use in rollers in pointing devices for several reasons. One reason is that very accurate mechanical alignment is required for such implementations, and such tight tolerances are very difficult to achieve during manufacture of pointing devices. Further, the information obtained from such systems is relative/incremental information rather than absolute positioning information.

Thus there is a need for a wheel assembly in an input device where the absolute angular position of the wheel is measured. Further, there is a need for a wheel configuration for use in a pointing device wherein the assembly has a smaller and more compact form factor. Moreover, there is need for a wheel configuration for use in a pointing device which can be manufactured easily and at a low cost. In addition, there is a need for a wheel with lower power consumption. Further still, there is a need for a wheel assembly where the sensor can be encased in a protective covering to minimize exposure to foreign articles as well as to minimize ESD issues. Moreover, there is a need for a wheel assembly, where tilting of the wheel can be measured using the same sensor used for measuring the rotation of the wheel. Furthermore, there is need for a pointing device with a wheel where the ratcheting action the user experiences is well synchronized with the effect of the rotation of the wheel.

### SUMMARY OF THE INVENTION

Embodiments of the present invention include a roller system for a pointing device, where the roller's absolute angular position is measured by a magnetic encoder, and which overcome the several issues discussed above.

In one embodiment, a magnet is attached to the roller. In one embodiment, the magnet is included inside the roller. A magnetic encoder provides information regarding the absolute angular position of the roller. It is to be noted that this is in contrast to the relative position information obtained in prior art rollers in pointing devices. Further, in one embodiment, the magnetization required is fairly simple, and is low cost. Moreover, tight tolerances are not required, and a system in accordance with an embodiment of the present invention is thus easy to manufacture.

As mentioned above, in one embodiment, the magnet is contained inside the wheel. In such a situation, the sensor is on one side of the wheel. In another embodiment, the magnet is attached to a side of the wheel, and the encoder/sensor is on the same side as the magnet. Components required for measuring the rotation of the wheel are only on one side of the wheel, thus leading to a much more compact assembly than conventional roller assemblies with components on both sides of the wheel for measuring rotation.

Further, since the sensor is a magnetic sensor, it can be covered by any non-ferromagnetic (non-metallic) material, without affecting its performance. Thus, in one embodiment, the sensor is covered (by a plastic case, for example) to protect it from dust and other foreign particles, without affecting the sensor's performance. Furthermore, in one embodiment, such casings also provide the encoder sensor being with electro-static discharge (ESD) protection, to reduce ESD issues.

A wheel implemented in accordance with an embodiment of the present invention consumes much less power than conventional wheels in pointing devices.

In one embodiment, the tilting of the wheel is measured using the same sensor that is used for measuring the rotation of the wheel. Thus separate switches, separate sensors, or other separate measuring mechanisms are not needed for measuring the tilt of a wheel in accordance with an embodiment of the present invention.

In one embodiment, a ratcheting feel provided to the user when rotating the wheel is synchronized with the rotation signal sent by the wheel to the host. The user thus receives more coordinated and realistic feedback from the wheel.

The present invention may be applied to many different domains, and is not limited to any one application or domain. Many techniques of the present invention may be applied to a different device in any domain. For instance, the input device under discussion need not only be a mouse or a trackball, but can also include other devices. Examples of such devices include remote controls used with a computer, remote controls used with devices in a user's entertainment system, in-air devices, presentation devices, personal digital assistants, personal media players, cell phones, digital tablets, netbooks, and so on.

The features and advantages described in this summary and the following detailed description are not all-inclusive, and particularly, many additional features and advantages will be apparent to one of ordinary skill in the art in view of the drawings, specification, and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE DRAWINGS

The invention has other advantages and features which will be more readily apparent from the following detailed description of the invention and the appended claims, when taken in conjunction with the accompanying drawing, in which:

FIG. 1A shows a conventional optical encoder with a light source and a photosensor.

FIG. 1B shows a cross-sectional view of a conventional optical encoder such as that shown in FIG. 1A.

FIG. 1C shows loss of light in conventional optical encoder such as those shown in FIGS. 1A and 1B.

FIG. 2A shows a prior art rotary wheel with alternating highly reflective and highly absorbent surfaces.

FIG. 2B shows the rotary wheel shown in FIG. 2A, with additional circuitry.

FIG. 3A shows a circular multi-pole magnet.

FIG. 3B shows a circular multi-pole magnet with a sensor.

FIG. 3C also shows a circular multi-pole magnet with a sensor.

FIG. 3D shows a linear multi-pole magnet with a sensor.

FIG. 4A shows a diametral magnet with a single north and a single south pole, along with a sensor.

FIG. 4B shows an implementation based on the dual-axis Hall sensor.

FIG. 5A shows a diametral magnet with a single north and a single south pole, along with a sensor.

FIG. 5B show an implementation based on vertical field measurements.

FIG. 6A shows a wheel with teeth made of ferromagnetic material.

FIG. 6B shows the wheel in FIG. 6A along with a sensor and magnet.

FIG. 6C shows a disk.

FIG. 6D shows a cup.

FIG. 7A shows a wheel assembly in accordance with an embodiment of the present invention.

FIG. 7B shows a second perspective of a wheel assembly in accordance with an embodiment of the present invention.

FIG. 7C shows a third perspective of a wheel assembly in accordance with an embodiment of the present invention.

FIG. 8 shows the electrical connections from sensor.

FIG. 9 shows the distances between the various components of a system in accordance with an embodiment of the present invention

FIG. 10 shows a diametrally magnetized dual-pole magnet.

FIG. 11 is a flowchart showing the steps taken to wake up an input device using the roller in accordance with an embodiment of the present invention.

FIG. 12A shows the distance between the magnet and the sensor when the wheel is not tilted.

FIG. 12B shows the distance between the magnet and the sensor when the wheel is tilted away from the sensor.

FIG. 12C shows the distance between the magnet and the sensor when the wheel is tilted towards the sensor.

FIG. 13A shows a graph where the magnetic field measured by the sensor is plotted against time, in accordance with an embodiment of the present invention.

FIG. 13B shows the amplitude of the magnetic field measured by the sensor, in accordance with an embodiment of the present invention.

FIG. 13C shows that ranges of amplitude values can indicate tilts of the wheel in accordance with an embodiment of the present invention.

FIG. 14 is a flowchart showing how a direction and an amplitude of a magnetic field are used in accordance with an embodiment of the present invention.

FIG. 15A shows a wheel with ratchet mechanism turning.

FIG. 15B shows the angular position of the wheel plotted against time.

FIG. 15C shows the velocity of the wheel plotted against time.

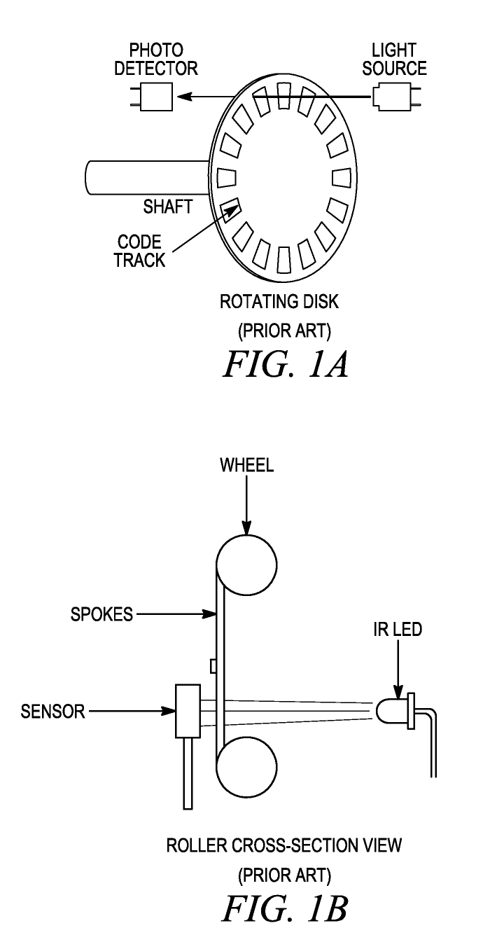

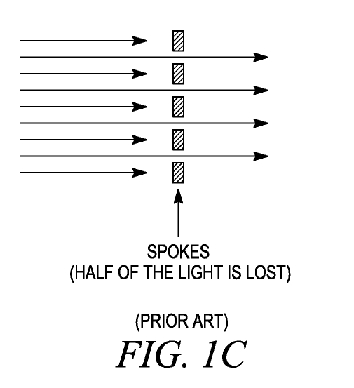

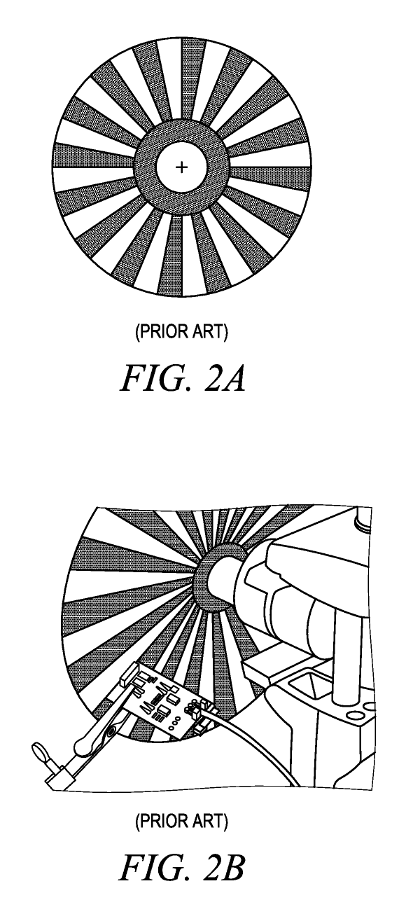

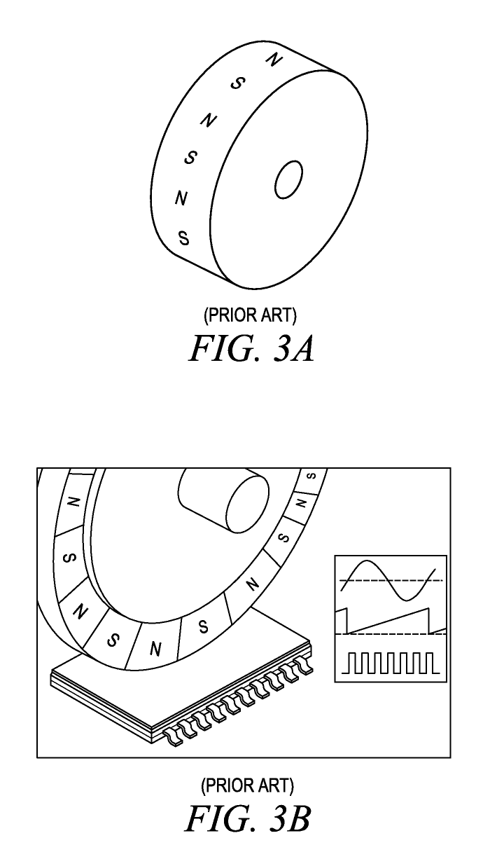

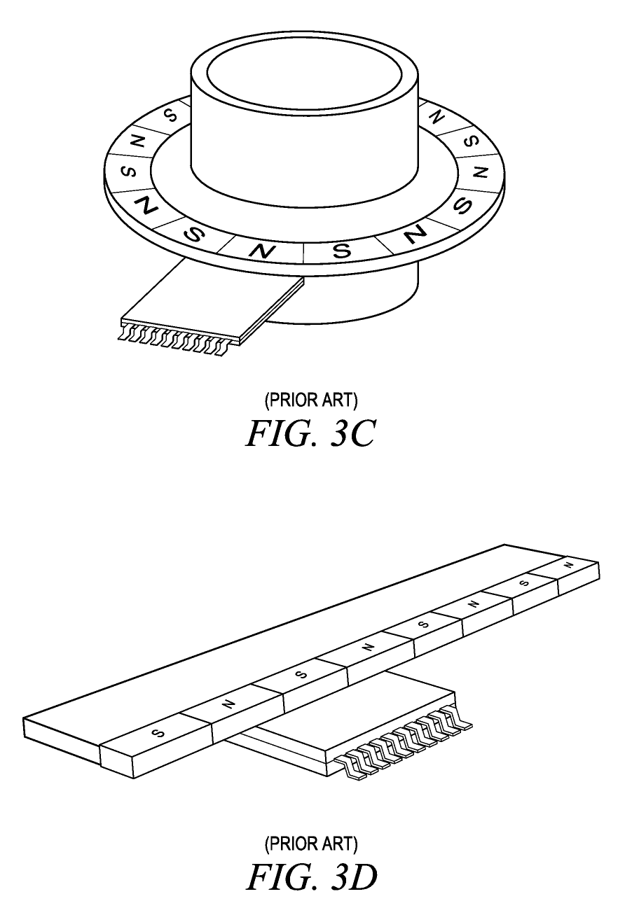

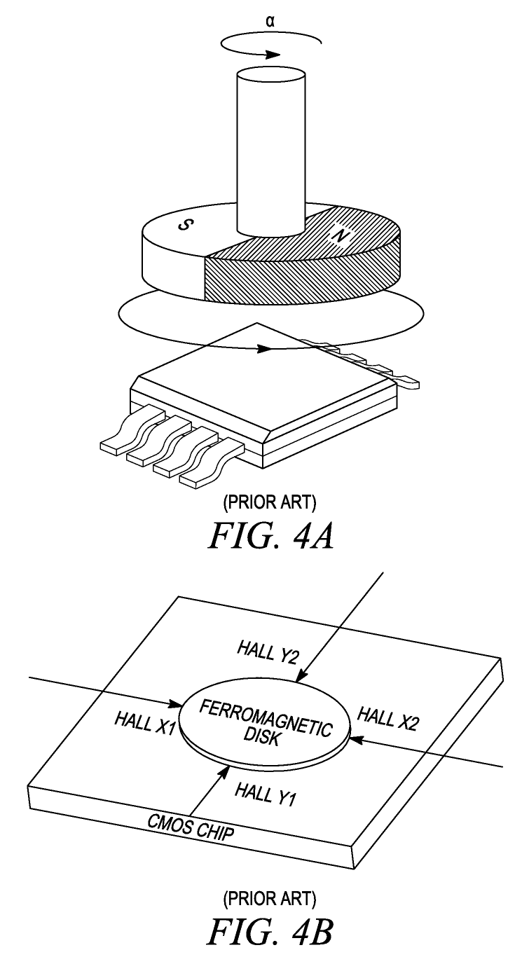

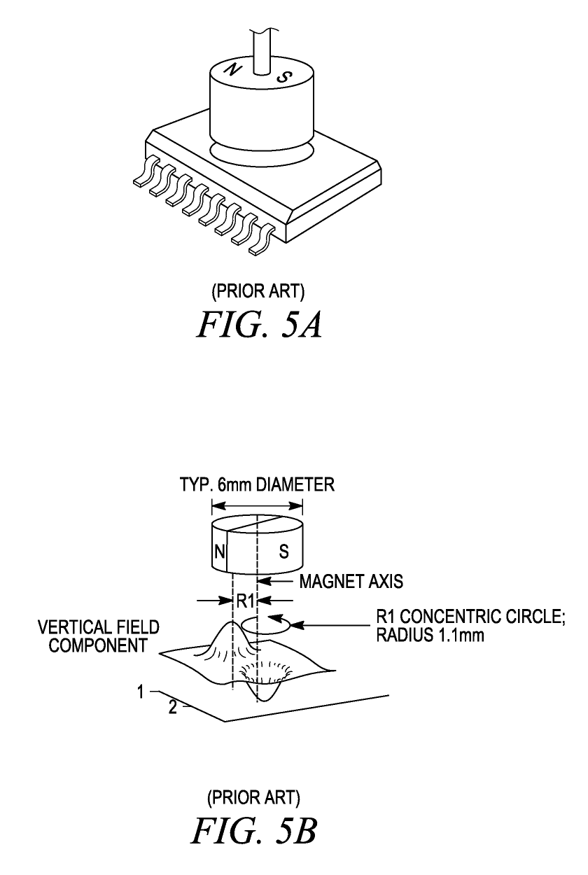

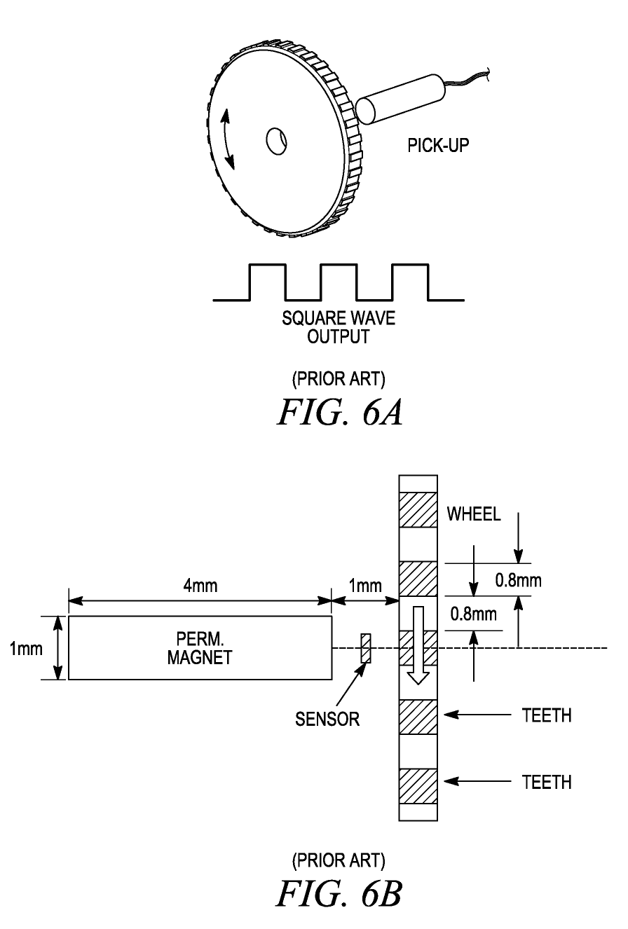

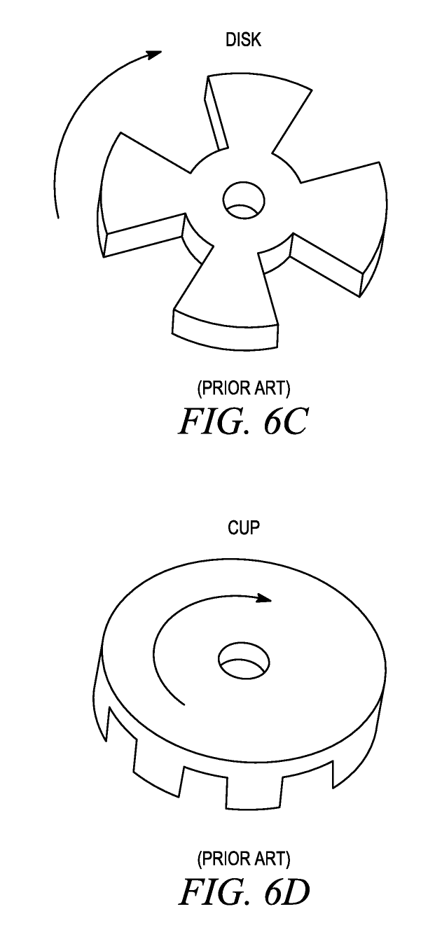

### DETAILED DESCRIPTION OF THE INVENTION

The figures (or drawings) depict a preferred embodiment of the present invention for purposes of illustration only. It is noted that similar or like reference numbers in the figures may indicate similar or like functionality. One of skill in the art will readily recognize from the following discussion that alternative embodiments of the structures and methods disclosed herein may be employed without departing from the principles of the invention(s) herein.

It is to be noted that the terms “wheel” and “roller” are used interchangeably herein. It is further to be noted that while most of the discussion here focuses on wheels in input devices, the present invention is not limited to such embodiments. Embodiments of the present invention can be used in input mechanisms in other devices which use angular movement. Examples include, but are not limited to, dials such as volume dials, buttons like digital potentiometers, tuning buttons, etc. It is to be noted that although the following description of the preferred embodiments of the present invention is presented in the context of a mouse, there are other devices that can use the present invention such as, for example, scanners, digital writing systems (e.g., Logitech 10 pen by Logitech, Inc. of Fremont, Calif.), remote control devices, presentation devices, trackballs, personal digital assistants, cell-phone, personal media players (e.g., iPod from Apple, Inc. (Cupertino, Calif.), digital tablets, and netbooks. It is to be noted that this list is meant to be illustrative rather than limiting.

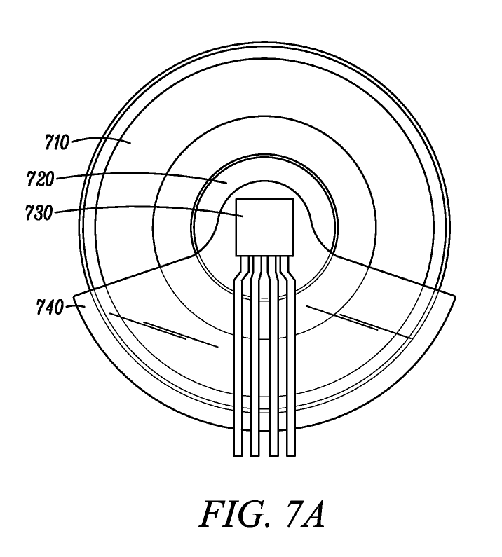

FIGS. 7A-7C show, from different perspectives, a wheel assembly 700 in accordance with an embodiment of the present invention. A wheel 710, a magnet 720, a sensor 730, and a wheel support 740 are shown.

The roller 710 is a roller or wheel. In accordance with an embodiment of the present invention, this wheel is used in a pointing device. It is to be noted, however, that a wheel in accordance with an embodiment of the present invention can be used in any devices which need to be small/portable, low cost, and easy to manufacture.

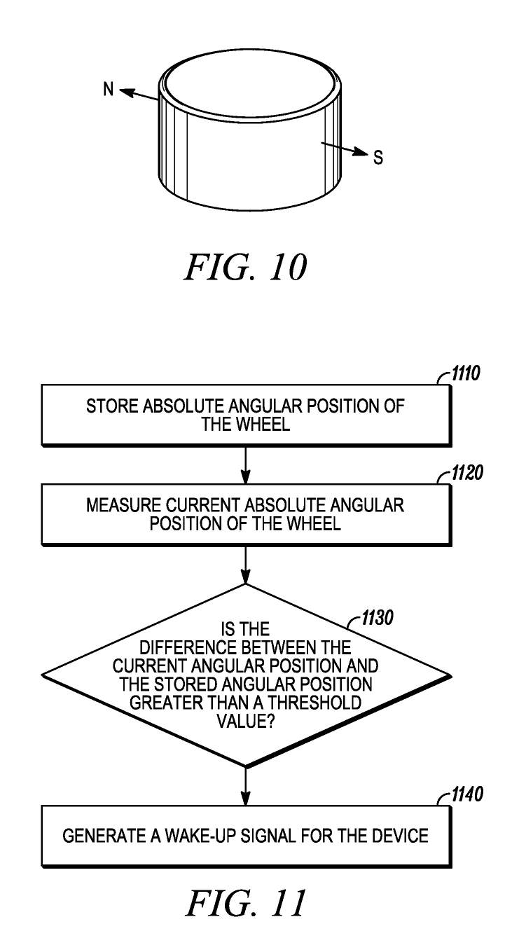

The magnet 720 is attached to the wheel 710. In particular, the magnet is attached to the wheel 710 in such a way that when the wheel is rotated, the magnet also rotates along with it. In one embodiment, the magnet 720 is a permanent magnet in accordance with an embodiment of the present invention. In one embodiment, magnet 720 is a dual pole magnet (having a North pole and a South pole) with diametral magnetization, such as the one shown in FIG. 10. The shape of the magnet can be varied. For example, in one embodiment, a ring-shaped magnet 720 is used. In another embodiment, a disc-shaped magnet is used. The magnet 720 is made of various materials in accordance with various embodiments of the present invention. For instance, magnet 720 may be a Neodymium-iron-boron magnet (NdFeB or NIB) (Rare Earth magnet), Samarium-cobalt magnet (SmCo) (Rare Earth magnet), Alnico magnet, Ferrite magnet (Ceramic magnet), Flexible magnet (Rubber magnet), electro-mechanical magnet, and so on. The amplitude of the magnetic field can vary as well. In one embodiment, the amplitude of the magnetic field varies between 20-200 mT (milli-Tesla).

Sensor 730 is a magnetic sensor which can measure the absolute position of the rotation of wheel 710. In one embodiment, sensor 730 is a Circular Vertical Hall Device (CVHD). Details regarding one implementation of a CMOS based CVHD sensor can be found in WO/2008/145662 by Popovic et al., which is hereby incorporated by reference herein in its entirety. It is to be noted that other sensors can be used in embodiments of the present invention.

In one embodiment, the sensor measures the absolute position of the wheel 710 and generates signals triggered by the rotation of the wheel. In one embodiment, these generated signals are provided to a microprocessor in the input device within which the wheel assembly 700 is used. In one embodiment, these generated signals are provided to a host (e.g., a PC) with which the input device communicates. In another embodiment, these generated signals are provided to a microprocessor in the input device, which in turn communicates these signals to the host.

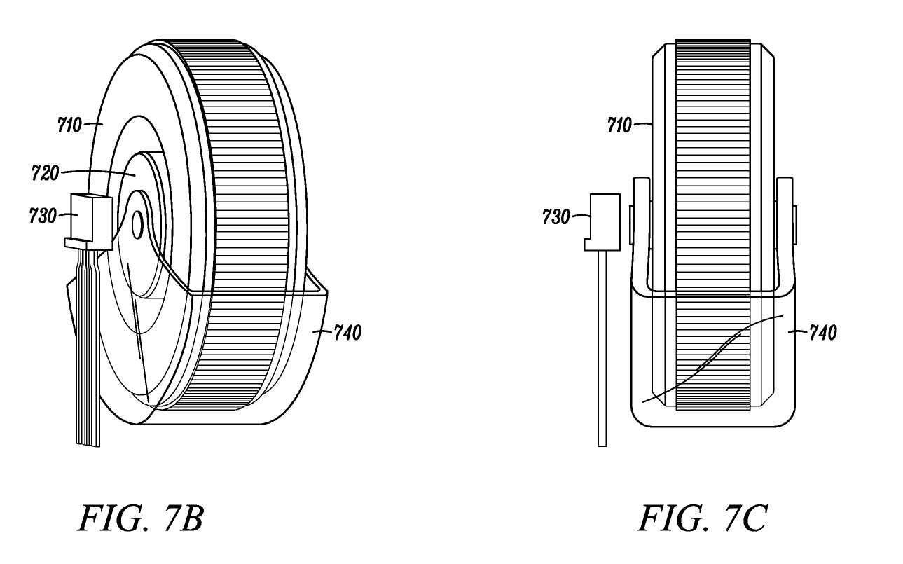

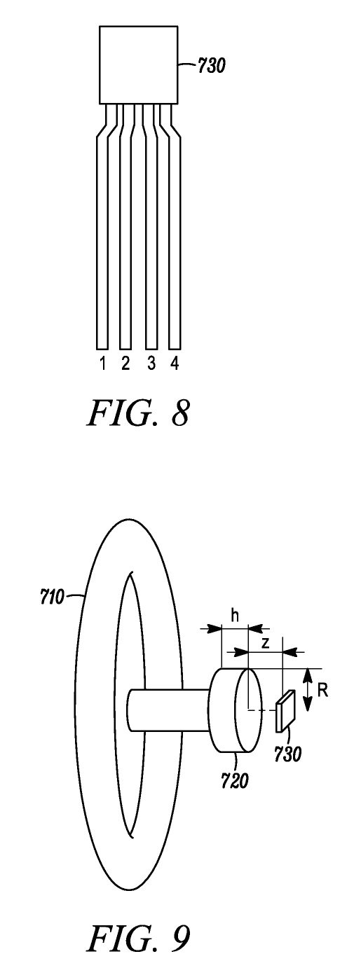

FIG. 8 shows the electrical connections from sensor 730 in accordance with an embodiment of the present invention. It can be seen that the sensor has 4 lines connected to it—the power line (1), ground (2), clock (3) and data (4). In another embodiment, the sensor 730 has only three lines—for power, ground, and data.

Referring again to FIGS. 7A-7C, it can be seen that the wheel support 740 supports the wheel 710, and can be made of various materials, such as plastic.

As mentioned above, the magnet 720 is attached to the wheel 710. It can be seen from FIGS. 7A-7C that in one embodiment, the magnet 720 is placed within the wheel 710. This provides for an extremely compact form factor, since the magnet 720 does not take up space on any side of the wheel 710. It is to be noted that in other embodiments, the magnet 720 is on one side of the wheel. In one such embodiment, the magnet 720 is on the same side of the wheel 710 as the sensor 730. This configuration is also more compact, when compared to the conventional optical configurations 1A-1C, where the light source and sensor are on opposite sides of the wheel.

FIG. 9 shows the distances between the various components of a system in accordance with an embodiment of the present invention. It is to be noted that for clarity in the figure, the embodiment shown here shows magnet 720 on one side of the wheel 710. However, as noted above, in other embodiments, the magnet 720 is placed within the wheel 710. The distances shown here in FIG. 9 can be applicable in those embodiments as well.

It can be seen from FIG. 9 that the width of the magnet 720 is “h”. The distance between the magnet 720 and the sensor 730 is “Z”. “R” is the radius of the magnet 720. In one embodiment, the central axis of the sensor 730 and the central axis of the magnet 720 are offset by a certain distance. A system in accordance with an embodiment of the present invention is robust does not require tight tolerances, and is tolerant to such offsets.

A wheel assembly in accordance with an embodiment of the present invention consumes less power than conventional wheels in pointing devices whose rotation is measured by optical means. In particular, for an optical system, the light source (e.g., LED or laser) consumes power in order to emit light. In contrast, the magnet 720 is a passive component which does not consume any power.

In one embodiment, the sensor 730 can be encased in various materials. Since the embodiments of the present invention use magnets (rather than optical measurements), the sensor can be cased in any materials that are not magnetic. For instance, the sensor can be encased in plastic. Such encasing does not affect the magnetic field in any way, but offers several advantages. Some examples of such advantages include protecting the sensor from dust and other foreign particles, reducing electro-static discharge (ESD), and so on. In contrast, in prior art wheels using optical technology to measure the rotation of the wheel, almost any type of cover on a sensor interferes with, or modifies, the optical path in some way, thus leading to erroneous measurements.

In another embodiment, a system in accordance with an embodiment of the present invention is easy to manufacture. As discussed above, conventional systems where optical technologies are employed, need to have accurate mechanical alignments to ensure that light emitted by the light source reaches the optical sensor. Such precise alignment is not needed for measurement of the magnetic field which is used in embodiments of the present invention. Thus greater tolerances are acceptable in systems in accordance with some embodiments of the present invention. This makes devices in accordance with embodiments of the present invention easier, and less expensive, to manufacture.

### Measurement of Absolute Angular Position of the Wheel

A system in accordance with an embodiment of the present invention measures the absolute angular position of the wheel 710. This is in contrast to measurement of the relative position (or incremental measurements) of the wheel rotations, where only the relative position (increase or decrease from before) is known, but there is no information about absolute position. Such measurement of the absolute position of the wheel 710 by the sensor 730 has several advantages, some of which are described below.

First, such a system can operate effectively with a lower report polling rate. In accordance with an embodiment of the present invention, for absolute angular position measurement, the polling rate can be as little as twice the wheel rotations in turns per second.

This is in contrast to conventional systems (like the conventional optical solutions) which measure incremental rotational movement of the wheel, where the polling rate needs to be at least 96 times faster than the wheel turns per second. With conventional optical rollers, typically, there are 24 ratchets, 48 slots, 48 spokes on the wheel that can generate 192 increments per turn. During a rotation, at every few increments (e.g., at every 4 increments or every 7.5°), there is a symmetry in the design. Since in these conventional optical wheels, the sensor does not know where the wheel is in absolute position, if the wheel rotates by 7.5° between every measurement, the sensor measures no motion at all. To avoid this, the sampling frequency has to be at least twice higher than the signal frequency (in accordance with the Nyquist-Shannon sampling theorem). Thus in this example, the wheel has to rotate less than 3.75° between measurements. Thus the polling has to be done at the rate of at least 96 per turn of the wheel.

In contrast, in the case of an absolute encoder in accordance with an embodiment of the present invention, the signal symmetry or frequency corresponds to a rotation of 360°. The sampling frequency has to ensure that the wheel rotates less than 180° between two measurements. So in this example, a sampling frequency can be 48 times lower with the absolute encoder to guarantee the Nyquist criterion. Thus, knowledge of the absolute position in embodiments of the present invention leads to a need for a significantly lower polling rate. This in turn implies less processing stress on the device (e.g., mouse) microcontroller, and in turn implies lower power consumption by the device in accordance with an embodiment of the present invention.

Another advantage is that a device including an assembly in accordance with an embodiment of the present invention can be woken up from a low power sleep state using the roller 710. FIG. 11 shows an implementation of this in one embodiment of the present invention. As can be seen from FIG. 11, the absolute position when the device entered sleep mode is stored (step 1110). Every once in a while, the current absolute position of the wheel 710 is measured (step 1120). This current absolute position of the wheel 710 is compared (step 1130) to the stored position. When the difference is more than a threshold value of a minimum angular motion, a wake-up signal is generated (step 1140) for the device. Waking up the device from a sleep state using the roller is not generally used in conventional rollers which use incremental (relative) roller encoders, since the power consumption in those cases would be very high, due to the high polling frequency that would be required to enable such functionality.

In embodiments of the present invention, by knowing the absolute angular position, the roller 710 can be calibrated in production to increase the resolution, precision and linearity.

It is to be noted that since, in accordance with the embodiments of the present invention, the absolute position of the roller 710 is measured, the roller 710 can be implemented and used as a knob or dial button with an absolute scale. Examples of applications include a volume knob graduated from 0 to 10, a zoom button with a stable reference position for a zoom condition of zoom=100%, mode selection dials, and so on. Another example is a dial to access predefined settings or profiles stored in the device, where markings may be printed on the wheel to visually recognize each setting. (In one embodiment, there are 24 ratchets on the wheel corresponding to 24 different settings or profiles which can be accessed easily and rapidly.) Still another example is to use the roller as a numpad in accordance with an embodiment of the present invention. In one embodiment, a click (or tilt) of the roller (or a click of a separate button) brings up a numerical pad on an associated display. In one embodiment, different numbers are presented in a rotating manner. In one embodiment, rotation of the roller causes different numbers to be brought up or selected. It is to be noted that the embodiments of the present invention are not limited to rollers or wheels, but rather can be used in any input mechanisms where rotation is to be measured.

### Measuring the Tilt of the Roller

In accordance with an embodiment of the present invention, the tilting of the wheel 710 can be measured using the same sensor 730 which is used to measure the absolute angular position of the wheel 710. In other words, no separate sensors, switches, etc. are required to measure the tilt of the wheel 710 in accordance with an embodiment of the present invention. This results in a more compact and lower cost tilting wheel implementation in input devices.

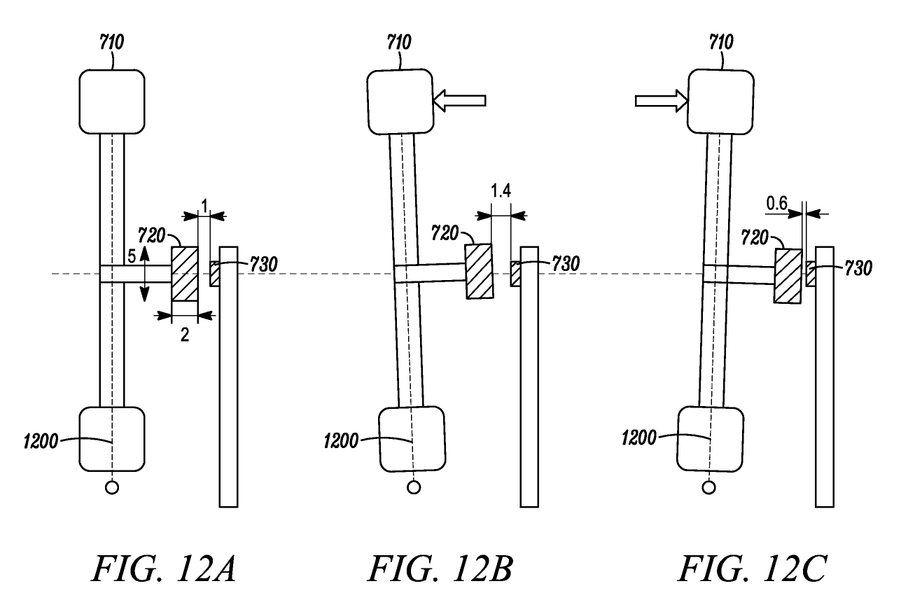

It can be seen from FIGS. 12A-12C that the distance between the magnet 720 and the sensor 730 changes when the wheel 710 is tilted. In FIG. 12A, the wheel 710 is not tilted away from the vertical plane, and the tilt axis 1200 is vertical. In the embodiment shown, when the wheel 710 is not tilted, the distance between the magnet 720 and the sensor 730 is 1 mm. In FIG. 12B, when the wheel 710 is tilted towards the left, the distance between the magnet 720 and the sensor 730 increases to 1.4 mm. In FIG. 12C, the wheel 710 is tilted towards the right, and the distance between the magnet 720 and the sensor decreases to 0.6 mm. It is to be noted that the exact distances mentioned herein are for illustration purposes only.

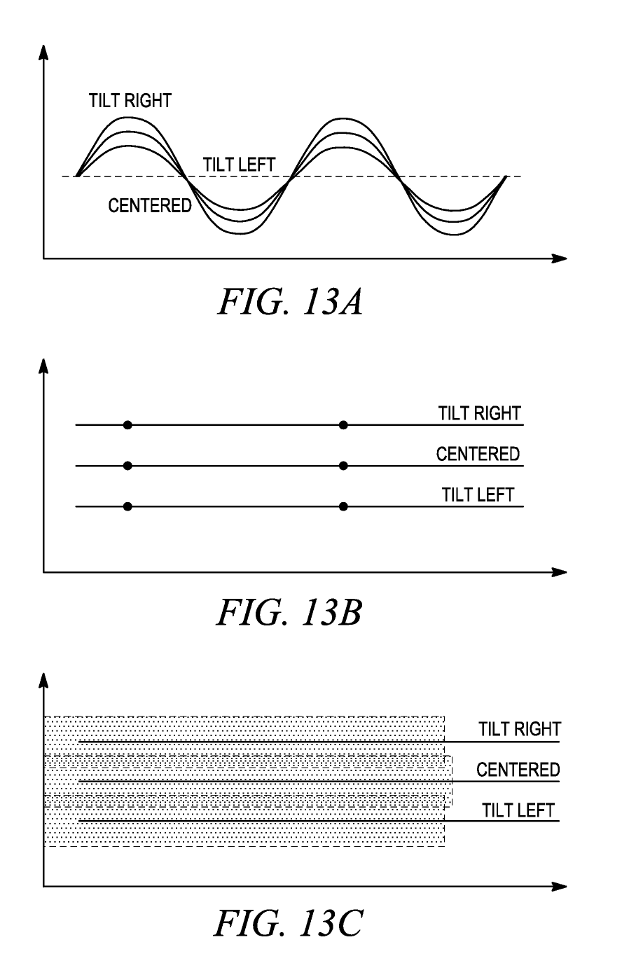

FIGS. 13A-13C show how the distance between the magnet 720 and the sensor 730 provides information regarding the tilting of the wheel 710. In FIGS. 13A-13C, the X-axis denotes time during the measurement, while the Y-axis denotes the magnetic field measured by the sensor 730. It can be seen that the amplitude of the sinusoidal wave in FIG. 13A provides information about the tilt of the wheel 710, while the phase of the sinusoidal wave in FIG. 13A provides information about the absolute angular position of the wheel 710. In FIG. 13B, the amplitude information is distilled out to easily assess the tilt of the wheel. It can be seen that when the wheel 710 and therefore magnet 720 are moved towards sensor 730 (a tilt to the right in the embodiment shown in FIGS. 12A-12C), this results in a larger amplitude than when the wheel 710 is centered (not tilted), while when wheel 710 and therefore magnet 720 are moved away from the sensor 730 (a tilt to the left in the embodiment shown in FIGS. 12A-12C), this results in a smaller amplitude than when the wheel 710 is centered (not tilted). FIG. 13C shows that in one embodiment, a range of amplitude values can be identified as indicating a tilt right, another range can be identified as indicating no tilt, and still another range can be identified as indicating a tilt left.

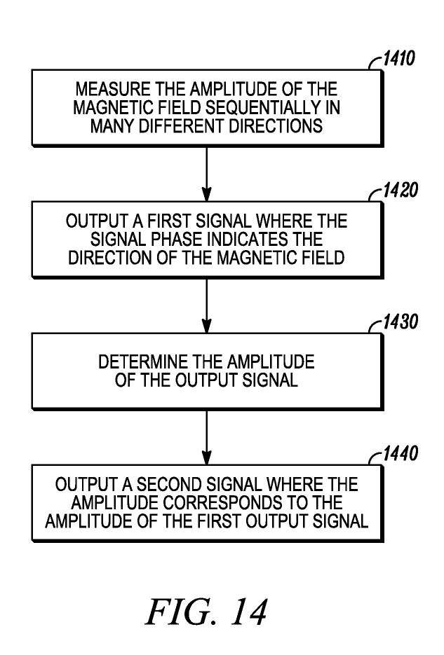

FIG. 14 shows a flowchart illustrating how a direction and amplitude of the magnetic field are used in one embodiment of the present invention. The amplitude of the magnetic field is measured (step 1410) in many different directions, allowing to encode the direction of the magnetic field with the phase of the output signal. The directions in which the maximum amplitude is detected provide the direction of the magnetic field. A first signal is outputted (step 1420) where the phase indicates the direction of the magnetic field, as shown in FIG. 13A. The amplitude of the output signal (e.g., a peak value or an average value) is measured (step 1430) and it provides information regarding the amplitude of the magnetic signal. A second signal is outputted (step 1440) which corresponds to the amplitude of the magnetic field, as shown in FIG. 13B. As mentioned above, in accordance with an embodiment of the present invention, the direction of the magnetic field is used to obtain the absolute position of the wheel 710, while the amplitude of the magnetic field is used to obtain information about the tilt of the wheel 710.

It is to be noted that for purposes of clarity, the embodiment shown in FIGS. 12A-12C has the magnet 720 on one side of the wheel 710. However, embodiments having the magnet 720 within the wheel 730 also function in the manner described above with regard to measuring the tilt of the wheel 730. As long as the magnet 720 is attached to the wheel 710, the tilt of the wheel 710 can be measured by the sensor 730 as described above, regardless of the exact location of the magnet 720.

Synchronizing Ratcheting Feel with the Rotation of the Wheel

As mentioned above, in order to have a good user experience, the ratcheting feel provided by a wheel needs to be coordinated with the rotation-triggered action generated. For instance, if the rotation-triggered action is scrolling on a display connected to a host with which the device with the wheel communicates, the scrolling signal sent to the host needs to be coordinated with the ratcheting feel. If this ratcheting feel is not synchronized accurately, the user is confused by receiving a ratcheting feel separately from an action (e.g., scrolling to the next line) happening. Thus, the quality of the feedback for the user is degraded.

In many mouse roller implementations with ratchets, the mouse reports to the host computer 24 ratchets per turn of the roller wheel. In order to do this, the incremental optical encoder measures 192 increments per turn, which are then aggregated into ratchet blocks, each made up of 8 increments. To give a notch feel to the user when he/she is rolling the wheel, mechanical ratchets are built within the conventional wheels and controlled by a spring. Therefore, there is a need to synchronize the mechanical ratchet angular position with the incremental angular position reported by conventional encoders.

In embodiments of the present invention also, mechanical ratchets are present to provide the user with the ratcheting feel. As mentioned above, various embodiments of the present invention make use a magnetic encoder which provides information regarding the absolute angular position of the wheel. Thus, in accordance with an embodiment of the present invention, ratchet synchronization is achieved by calibrating the device on the production line. As mentioned above, in embodiments of the present invention, losing counts is largely avoided. In one embodiment, ratchet re-synchronization is not needed as losing counts can be avoided in embodiments of the present invention.

In one embodiment, however, even when the device is calibrated during manufacture, several factors (such as even minimal non-linearity, hysteresis, drift, etc.) cause the ratcheting feel to become, over time, out-of-sync with the rotation signals measured by the sensor 730. Therefore, in one embodiment, the measured angular position is re-synchronized with the mechanical ratchets. In one embodiment, no initial synchronization is performed on the production line, and the measured angular position is simply synchronized with the mechanical ratchets as described below. This can be done by detecting when the wheel 710 is not turning. Then successive measurements will have the same value, meaning that the wheel is in stable ratchet position. When this occurs, the absolute angular position measured can be realigned with the mechanical ratchet.

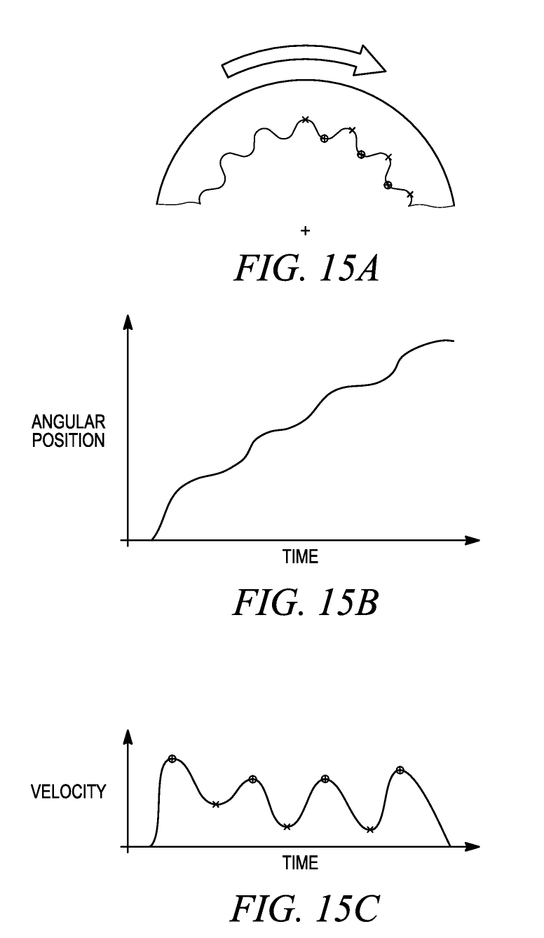

FIGS. 15A-15C illustrate how the mechanical ratcheting feel is synchronized with the rotation signals measured by the sensor 730. These figures illustrate how ratchet synchronization is calibrated on the production line, in accordance with an embodiment of the present invention, as well as how the ratchets can be re-synchronized during the lifetime of the device in accordance with an embodiment of the present invention. FIG. 15A shows the wheel 710 turning. FIG. 15B shows the angular position of the wheel 710 plotted against time, while FIG. 15C shows the angular velocity of the wheel 710 plotted against time. The angular velocity can be calculated based upon the measurements of angular position over time. In accordance with an embodiment of the present invention, in ratchet mode, when the user turns the roller with his finger, the wheel motion will not be exactly linear. It will accelerate in between two ratchet positions and tend to slow down in the middle of the ratchet stable position.

In one embodiment, based upon measurements of the angular position, the wheel angular velocity over time is obtained. The velocity local maxima and local minima are then analyzed to determine the mechanical position of the ratchet. It is to be noted that by knowing the absolute angular position, the velocity signal can be overlapped over several turns of the wheel and positioned precisely relative to the wheel mechanics, thus increasing the overall precision of the position and velocity analysis.

Once the angular position of each ratchet is precisely known in the coordinate frame of the rotary encoder (sensor 730), in one embodiment, a rotation-triggered command (e.g., a scroll signal) is generated exactly when the transition between two mechanical ratchet occurs, thus improving the quality of the ratchet feedback for the user. In one embodiment, the rotation-triggered command is generated when each ratchet occurs. In one embodiment, the rotation-triggered command is generated both between two mechanical ratchets, and when the mechanical ratchets occur. In one embodiment, the rotation-triggered command is sent to a host (e.g., computer) with which the device communicates.

While particular embodiments and applications of the present invention have been illustrated and described, it is to be understood that the invention is not limited to the precise construction and components disclosed herein. For example, an input device in accordance with embodiments of the present invention can be a remote control used to control components of the user's multi-media system (e.g., a TV, DVD player, etc.). As another example, any of the above-mentioned embodiments can be applied to any situation where rotational movement is to be measured in a compact device, which needs to be manufactured at a low cost. Various other modifications, changes, and variations which will be apparent to those skilled in the art may be made in the arrangement, operation and details of the method and apparatus of the present invention disclosed herein, without departing from the spirit and scope of the invention as defined in the following claims.

What is claimed is:

1. A wheel assembly for use in an input device, the wheel assembly comprising:
a wheel;
a magnet coupled to the wheel, wherein the coupling is such that the magnet rotates with the wheel; and
a magnetic sensor for measuring the absolute position of the magnet, wherein the sensor provides signals triggered by rotation of the wheel.

2. The wheel assembly of claim 1, wherein the magnet is a permanent magnet.

3. The wheel assembly of claim 1, wherein the magnet is a diametrically magnetized dual pole magnet.

4. The wheel assembly of claim 1, wherein the magnet is placed within the wheel.

5. The wheel assembly of claim 1, wherein the magnet is placed on a first side of the wheel, and the sensor is placed on the first side of the wheel.

6. The wheel assembly of claim 1, wherein the sensor provides signals triggered by rotation of the wheel to the input device.

7. The wheel assembly of claim 1, wherein the sensor provides signals triggered by rotation of the wheel to a host to which the input device is communicatively coupled.

8. The wheel assembly of claim 1, wherein the sensor provides information regarding a tilt of the wheel away from a vertical plane.

9. The wheel assembly of claim 1, wherein the wheel assembly is used to wake up the input device from a sleep state.

10. The wheel assembly of claim 1, wherein the wheel assembly consumes low power.

11. The wheel assembly of claim 1, wherein the sensor has a protective covering.

12. The wheel assembly of claim 11, wherein the protective covering reduces electro-static discharge

13. The wheel assembly of claim 11, wherein the protective covering provides a barrier to entry of foreign materials.

14. A method for measuring rotation and tilt of a wheel in an input device, the wheel having a magnet coupled to it, wherein the input device includes a sensor for measuring a magnetic field generated by the magnet, the method comprising:
measuring the amplitude of the magnetic field sequentially in a plurality of directions;
determining a direction of the magnetic field based upon the measurement;
generating a first signal based upon a direction of the magnetic field;
determining a value of an amplitude of the first signal; and
generating a second signal based upon the amplitude of the first signal, wherein the first signal provides information regarding rotation of the wheel, and the second signal provides information regarding tilt of the wheel.

15. The method of claim 14, further comprising:
providing at least one of the generated first and second signals to the input device.

16. The method of claim 14, further comprising:
providing at least one of the generated first and second signals to a host with which the input device communicates.

17. The method of claim 14, further comprising:
synchronizing a mechanical ratchet feel experienced by a user of the input device, with the generated first signal.

18. The method of claim 17, wherein the synchronizing is performed during manufacture of the wheel.

19. The method of claim 17, wherein the synchronizing is performed during usage of the wheel.

20. The method of claim 17, wherein the synchronizing comprises:
calculating the velocity of rotation of the wheel; and
analyzing local maxima and local minima of the velocity.

21. A method of manufacture of a wheel assembly for use in an input device, the method comprising:
positioning a wheel within a wheel support, such that the wheel is rotatable by a user's finger;
coupling a magnet to the wheel, wherein the coupling is such that the magnet rotates with the wheel; and
positioning a magnetic sensor in the proximity of the wheel, wherein the magnetic sensor measures the absolute position of the magnet, and wherein the sensor provides signals triggered by rotation of the wheel.

22. The method of manufacture of claim 21, further comprising:
covering the sensor with a protective covering.

23. The method of manufacture of claim 21, further comprising:
calibrating the wheel to synchronize the signals triggered by the rotation of the wheel with a ratcheting feel experienced by the user's finger.
